(19) United States
(12) Patent Application Publication
(10) Pub. No.: US 2025/0204213 A1
(43) Pub. Date: Jun. 19, 2025

(54) DISPLAY DEVICE AND METHOD OF MANUFACTURING THE SAME

(71) Applicant: LG DISPLAY CO., LTD., Seoul (KR)

(72) Inventor: Dal Jae LEE, Paju-si (KR)

(73) Assignee: LG DISPLAY CO., LTD., Seoul (KR)

(21) Appl. No.: 18/774,365

(22) Filed: Jul. 16, 2024

(30) Foreign Application Priority Data
Dec. 13, 2023 (KR) 10-2023-0180910

(51) Int. Cl. H10K 59/80; H10K 59/126

(52) U.S. Cl. CPC H10K 59/8721; H10K 59/126; H10K 59/8722; H10K 59/8791

(57) ABSTRACT

A display device and a method of manufacturing the same which are capable of effectively preventing side-surface moisture penetration while achieving simplification of a process are disclosed. The display device includes a back plate, a display panel bonded onto the back plate, a cover glass bonded onto the display panel, and a sealing member configured to seal a side surface of the display panel and formed of a meltable metal.

### CROSS-REFERENCE TO RELATED APPLICATIONS

This application claims the priority of Korean Patent Application No. 10-2023-0180910, filed on Dec. 13, 2023, which is hereby incorporated by reference in its entirety.

### BACKGROUND

### Field of the Disclosure

The present disclosure relates to a display device and a method of manufacturing the same, and more particularly to a display device and a method of manufacturing the same which are capable of effectively preventing side-surface moisture penetration while achieving process simplification.

### Description of the Background

In recent years, with the advent of the information age, the field of displays configured to visually express electrical information signals has rapidly developed. As such, a variety of flat display devices having excellent performance such as slimness, lightness and low power consumption have been developed and used.

As concrete examples of such flat display devices, there may be a liquid crystal display (LCD) device, an organic light emitting display (OLED) device, an electrophoretic display (EPD) device, a plasma display panel (PDP) display device, an electrowetting display (EWD) device, etc. In particular, the organic light emitting display device is a next-generation display device having self-luminous characteristics and has excellent characteristics in terms of viewing angle, contrast, response time, power consumption, etc., as compared to the liquid crystal display device.

In recent years, a flexible display device using a substrate made of a flexible material such as plastic or the like to have flexibility has been highlighted as a next-generation display device. Currently, such a flexible display device has a wide application range not only including a monitor of a computer, a TV, and a personal portable appliance, but also including a navigation system for a vehicle or a dashboard for a vehicle.

In addition, a recent trend in display devices is to reduce bezel size.

As the bezel size of a display device is reduced, an area in which a sealing member is not coated may be formed or coating of the sealing member may have a smaller thickness than a lower limit thickness due to variation of parts and process deviation and, as such, a side-surface sealing defect of the display device may be generated.

### SUMMARY

Accordingly, the present disclosure is directed to a display device and a method of manufacturing the same that substantially obviate one or more problems due to limitations and disadvantages described above.

More specifically, the present disclosure is to provide a display device and a method of manufacturing the same in which a meltable metal is disposed in a trimming region and is then cut using a laser, and, as such, seals a side surface of the display device while being melted by cutting heat of the laser.

The present disclosure is not limited to the above-described, and other features of the present disclosure not yet described will be more clearly understood by those skilled in the art from the following detailed description.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described herein, a display device includes a back plate, a display panel bonded onto the back plate, a cover glass bonded onto the display panel, and a sealing member configured to seal a side surface of the display panel and formed of a meltable metal.

The meltable metal of the sealing member may include one of lead, copper, aluminum, and silver.

The display device may further include a polarization plate disposed between the display panel and the cover glass. The back plate and the display panel may be bonded to each other by an adhesive. The cover glass and the polarization plate may be bonded to each other by a transparent adhesive.

In another aspect of the present disclosure, a display device includes a back plate, a display panel bonded onto the back plate, a cover glass bonded onto the display panel, and a sealing member configured to seal side surfaces of the back plate and the display panel and formed of a meltable metal.

In another aspect of the present disclosure, a method of manufacturing a display device includes preparing a display panel including at least two OLED display panel regions, and a trimming region disposed between the at least two OLED display panel regions and formed with a meltable metal pattern, bonding the display panel onto a back plate, bonding a transparent adhesive to an upper surface of the display panel, and irradiating a central portion of the meltable metal pattern formed in the trimming region with a laser, thereby cutting a resultant structure into unit display panel regions and, simultaneously, melting the meltable metal pattern by heat of the laser, to form a sealing member configured to seal a side surface of the display panel.

The method may further include bonding a cover glass onto the transparent adhesive cut into the unit display panel regions.

Each of the OLED display panel regions may include a thin film transistor, and a light shielding layer disposed under the thin film transistor. The light shielding layer and the meltable metal pattern may be formed on the same layer using the same material.

In another aspect of the present disclosure, a method of manufacturing a display device includes preparing a display panel including at least two OLED display panel regions, and a trimming region disposed between the at least two OLED display panel regions, bonding the display panel onto a back plate, bonding a transparent adhesive to an upper surface of the display panel, forming a meltable metal pattern at a back surface of the back plate in the trimming region, and irradiating a central portion of the meltable metal pattern with a laser, thereby cutting a resultant structure into unit display panel regions and, simultaneously, melting the meltable metal pattern by heat of the laser, to form a sealing member configured to seal side surfaces of the back plate, the display panel, and the transparent adhesive.

In the display devices having the above-described features according to the present disclosure and the methods of manufacturing the same, there are effects as follows.

First, in the flexible OLED display device according to each aspect of the present disclosure, it may be possible to prevent moisture from being introduced into the OLED display panel because the meltable metal pattern is melted when cutting is carried out on the basis of a unit OLED display device and, as such, the side surface of the OLED display panel or the side surfaces of the back plate, the adhesive, the OLED display panel, the polarization plate, and the transparent adhesive are sealed by a melted metal of the meltable metal pattern.

Second, process simplification may be achieved because the side surface of the OLED display panel or the side surface of the display device is sealed by a melted metal when cutting is carried out on the basis of a unit OLED display device.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate various aspects of the disclosure and along with the description serve to explain the principle of the disclosure.

In the drawings:

FIG. 1 is a block diagram briefly showing a configuration of a display device according to an aspect of the present disclosure;

FIG. 2 is a circuit diagram of a sub-pixel included in a flexible display device according to an aspect of the present disclosure;

FIG. 3 is a sectional view schematically showing a configuration of one end of the flexible OLED display device according to a first aspect of the present disclosure;

FIG. 4 is a sectional view of a mother substrate of a display panel 100 explaining the method of manufacturing the flexible OLED display device according to the first aspect of the present disclosure;

FIGS. 5A to 5C are process sectional views explaining a method of manufacturing the flexible OLED display device according to the first aspect of the present disclosure;

FIG. 6 is a sectional view schematically showing a configuration of one end of the flexible OLED display device according to a second aspect of the present disclosure; and

FIGS. 7A to 7C are process sectional views explaining a method of manufacturing the flexible OLED display device according to the second aspect of the present disclosure.

### DETAILED DESCRIPTION

Advantages and features of the present disclosure and methods for achieving the same will be made clear from aspects described below in detail with reference to the accompanying drawings. The present disclosure may, however, be embodied in many different forms, and should not be construed as being limited to the aspects set forth herein. Here, aspects of the present disclosure are provided so that the present disclosure may be sufficiently thorough and complete to assist those skilled in the art in fully understanding the scope of the present disclosure. The present disclosure may be defined by the scope of the claims.

In the drawings for explaining the exemplary aspects of the present disclosure, for example, the illustrated shape, size, ratio, angle, and number are given by way of example, and thus, are not limited to the present specification. Throughout the present specification, the same reference numerals designate the same constituent elements. In addition, in the following description of the present disclosure, a detailed description of known functions and configurations incorporated herein will be omitted when it may make the subject matter of the present disclosure rather unclear.

The terms “comprises” “includes” and/or “has”, used in this specification, do not preclude the presence or addition of other elements unless used along with the term “only”. The singular forms are intended to include the plural forms as well, unless the context clearly indicates otherwise.

In interpretation of constituent elements included in the various aspects of the present disclosure, the constituent elements are interpreted as including an error range even if there is no explicit description thereof.

In the description of the various aspects of the present disclosure, when describing positional relationships, for example, when the positional relationship between two parts is described using “on”, “above”, “below”, “next to”, or the like, one or more other parts may be located between the two parts unless the term “directly” or “closely” is used.

It may be understood that, although ordinal numbers “first”, “second”, etc. may be used herein to distinguish constituent elements from one another, functions or structures of these elements are not to be limited by ordinal numbers or names of the elements. Since the claims are described mainly in conjunction with essential constituent elements, the ordinal number prefixed to the name of each constituent element in the claims may not be identical to the ordinal number used in the description of the aspects.

The respective features of the various aspects of the present disclosure may be partially or entirely coupled to and combined with each other, and various technical linkages and modes of operation thereof are possible. These various aspects may be performed independently of each other, or may be performed in association with each other.

Hereinafter, a display device according to an aspect of the present disclosure will be described in detail with reference to the accompanying drawings.

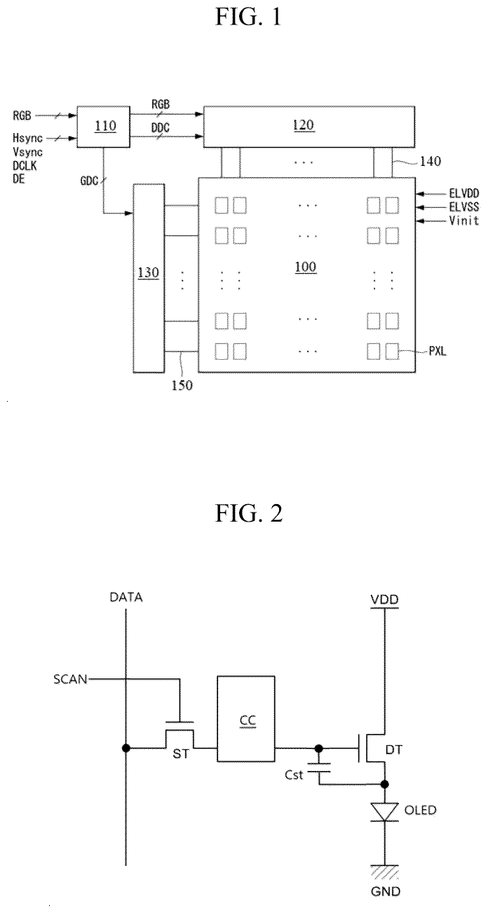

FIG. 1 is a block diagram briefly showing a configuration of a display device according to an aspect of the present disclosure.

Referring to FIG. 1, the display device according to the aspect of the present disclosure includes a display panel 100 formed with a plurality of pixels PXL arranged in a matrix form, a data driving circuit 120 configured to drive data lines 140, a gate driving circuit 130 configured to drive gate lines 150, and a timing controller 110 configured to control driving timings of the data driving circuit 120 and the gate driving circuit 130.

In the display panel 100, a plurality of data lines 140 and a plurality of gate lines 150 intersect each other, and pixels PXL are disposed in respective intersection areas in a matrix form. The pixels PXL disposed on the same horizontal line constitute one pixel row. The pixels PXL disposed on one pixel row are connected to one gate line 150, and one gate line 150 may include at least one scan line and at least one emission line. That is, each pixel PXL may be connected to one data line 140, at least one scan line, and at least one emission line. The pixels PXL may receive, in common, high-level and low-level drive voltages ELVDD and ELVSS and an initialization voltage Vinit from a power generator (not shown). To prevent unnecessary light emission of a light emitting element, for example, an organic light emitting diode (OLED), in an initialization period and a sampling period, the initialization voltage Vinit may be selected within a voltage range sufficiently lower than an operating voltage of the OLED, and may be set to be equal to or lower than the low-level drive voltage ELVSS.

Thin film transistors (TFTs) constituting each pixel PXL may each be implemented by an oxide TFT including an oxide semiconductor layer. The oxide TFT is advantageous in that the display panel 100 may have a large area, wholly taking into consideration electron mobility, process deviation, etc. However, the present disclosure is not limited to the above-described condition, and the semiconductor layer of each TFT may be formed of amorphous silicon, polysilicon, or the like.

Each pixel PXL may include a driving TFT configured to supply current to the light emitting element, that is, the OLED, a switching TFT configured to supply a data voltage to the driving TFT, and a storage capacitor configured to maintain the data voltage supplied to the driving TFT for one frame. Each pixel PXL may further include a plurality of TFTs and a storage capacitor to compensate for a variation in threshold voltage of the driving TFT.

The timing controller 110 rearranges digital video data RGB input thereto from outside, corresponding to a resolution of the display panel 100, and then supplies the rearranged digital video data RGB to the data driving circuit 120. In addition, the timing controller 110 generates a data control signal DDC for control of the operation timing of the data driving circuit 120 and a gate control signal GDC for control of the operation timing of the gate driving circuit 130, based on timing signals such as a vertical synchronization signal Vsync, a horizontal synchronization signal Hsync, a dot clock signal DCLK, a data enable signal DE, etc.

The data driving circuit 120 converts the digital video data RGB input thereto from the timing controller 110 into an analog data voltage, based on the data control signal DDC, and provides the analog data voltage to each data line 140.

The data driving circuit 120 may include at least one source drive IC (SIC). The source drive IC (SIC) converts digital video data of an input image into an analog gamma compensation voltage under control of the timing controller 110, thereby generating a data voltage, and outputs the data voltage to the data lines 140. The source drive IC (SIC) may be mounted on a flexible circuit board, which may be bent, for example, a chip-on-film (COF), or may be directly bonded to a substrate in a non-active area of the display panel 100 through a chip-on-glass (COG) process.

COFs as described above are bonded to a pad area of the display panel 100 and a source PCB through an anisotropic conductive film (ACF). Input pins of the COFs are electrically connected to output terminals (pads) of the source PCB. Output pins of the COFs are electrically connected to data pads formed at the substrate of the display panel 100 through the AFC.

The gate driving circuit 130 may generate a scan signal and an emission signal based on the gate control signal GDC. The gate driving circuit 130 may include a scan driver and an emission driver. The scan driver may generate a scan signal and may supply the scan signal to the gate lines 150 in a row sequential manner, to drive at least one scan line connected to each pixel row. The emission driver may generate an emission signal and may supply the emission signal to the emission lines in a row sequential manner, to drive at least one emission line connected to each pixel row.

The gate driving circuit 130 as described above may be directly formed on the non-active area of the display panel 100 in a gate-driver-in-panel (GIP) manner.

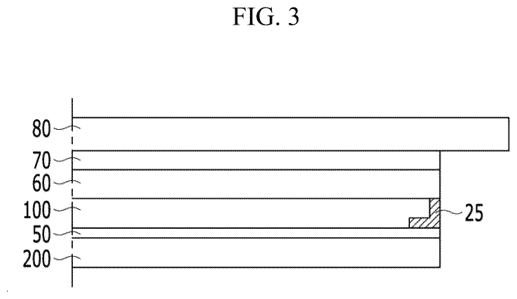

FIG. 2 is a circuit diagram of a sub-pixel included in a flexible display device according to an aspect of the present disclosure.

Referring to FIG. 2, the sub-pixel of the flexible display device according to the aspect of the present disclosure may include a switching transistor ST, a driving transistor DT, a compensation circuit CC, a light emitting element OLED, and a storage capacitor Cst.

The light emitting element OLED may operate to emit light in accordance with a drive current generated by the driving transistor DT.

The switching transistor ST may perform a switching operation to enable a data signal supplied through a data line DATA to be stored in the storage capacitor Cst as a data voltage, corresponding to a scan signal supplied through a gate line SCAN.

The driving transistor DT may operate to enable a constant drive current between a high-level voltage line VDD and a low-level voltage line GND, corresponding to the data voltage stored in the storage capacitor Cst.

The compensation circuit CC is a circuit for compensating a threshold voltage of the driving transistor DT or the like. The compensation circuit CC may include at least one thin film transistor and a capacitor. The configuration of the compensation circuit CC may be very diverse in accordance with compensation methods applied thereto.

For example, although the sub-pixel shown in FIG. 2 is configured to have a 2T (transistor) 1C (capacitor) structure including the switching transistor ST, the driving transistor DT, the storage capacitor Cst, and the light emitting element OLED, the sub-pixel may be configured to have various structures of 3T1C, 4T2C, 5T2C, 6T1C, 7T1C, 7T2C, etc. when the compensation circuit CC is added thereto.

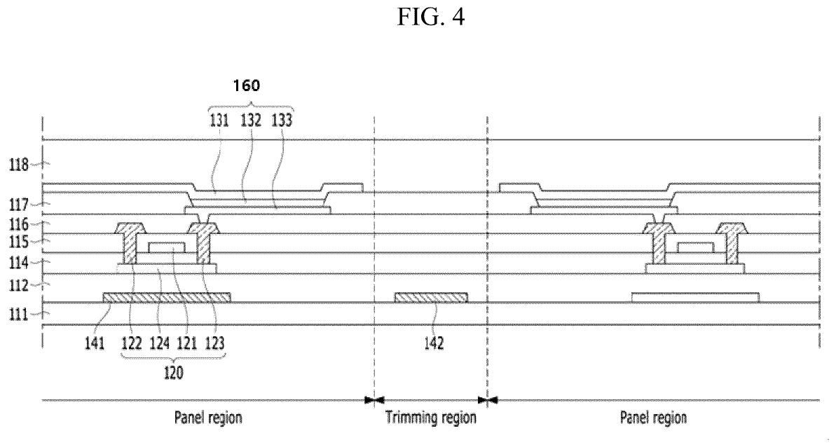

FIG. 3 is a sectional view schematically showing a configuration of one end of the flexible OLED display device according to a first aspect of the present disclosure.

As shown in FIG. 3, the flexible OLED display device according to the first aspect of the present disclosure may be configured through inclusion of a back plate 200, an OLED display panel 100, a polarization plate 60, and a cover glass 80.

The back plate 200 and the OLED display panel 100 may be bonded to each other by an adhesive 50 which may be a pressure-sensitive adhesive (PSA). The polarization plate 60 may be disposed on the OLED display panel 100. The polarization plate 60 and the cover glass 80 may be bonded to each other by a transparent adhesive 70 which may be an optically clear adhesive (OCA).

In addition, a side surface of the OLED display panel 100 may be sealed by a sealing member 25 formed of a meltable metal.

Here, as the meltable metal of the sealing member 25, a metal material having a low melting point, for example, lead (Pb), copper (Cu), aluminum (Al), silver (Ag), or the like, may be used.

The back plate 200 may take the form of a film including one of the group consisting of a polyester-based polymer, a silicon-based polymer, an acryl-based polymer, a polyolefin-based polymer, and a copolymer thereof.

Hereinafter, a method of manufacturing the flexible OLED display device according to the first aspect of the present disclosure configured as described above will be described.

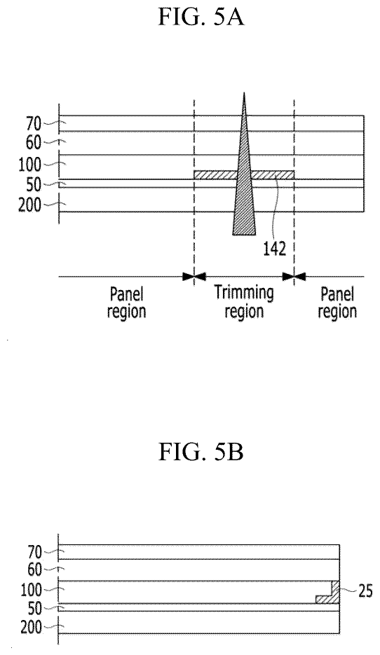

FIG. 4 is a sectional view of a mother substrate of the display panel 100 explaining the method of manufacturing the flexible OLED display device according to the first aspect of the present disclosure.

FIG. 4 shows that at least two OLED display panel regions and a trimming region between the at least two OLED display panel regions are provided at the mother substrate.

FIG. 4 shows that the driving transistor DT and the light emitting element OLED of the sub-pixel described with reference to FIG. 2 are disposed in each OLED display panel region.

A substrate 111 functions to support and protect constituent elements of a flexible display device 100 disposed thereon. As the substrate 111, a flexible substrate made of a soft material having flexible characteristics, such as plastic, may be used. Hereinafter, the flexible substrate will be designated by reference numeral “111”.

The flexible substrate 111 may take the form of a film including one of the group consisting of a polyester-based polymer, a silicon-based polymer, an acryl-based polymer, a polyolefin-based polymer, and a copolymer thereof.

A buffer layer 112 may be further disposed over the flexible substrate 111. The buffer layer 112 may prevent penetration of ambient moisture or other impurities through the flexible substrate 111 and may planarize a surface of the flexible substrate 111.

A thin film transistor 120 may be disposed over the flexible substrate 111 and may include a gate electrode 121, a source electrode 122, a drain electrode 123, and a semiconductor layer 124.

In this case, the semiconductor layer 124 may be constituted by amorphous silicon or polycrystalline silicon, without being limited thereto. Polycrystalline silicon has excellent mobility, as compared to amorphous silicon, and, as such, may have excellent reliability while exhibiting low energy consumption. In this regard, polycrystalline silicon is applicable to a driving thin transistor in a pixel.

The semiconductor layer 124 may be constituted by an oxide semiconductor. The oxide semiconductor has excellent characteristics in terms of mobility and uniformity. The oxide semiconductor may be constituted by an indium-tin-gallium-zinc oxide (InSnGaZnO)-based material, which is a quaternary metal oxide, an indium-gallium-zinc oxide (InGaZnO)-based material, an indium-tin-zinc oxide (InSnZnO)-based material, a tin-gallium-zinc oxide (SnGaZnO)-based material, an aluminum-gallium-zinc oxide (AlGaZnO)-based material, an indium-aluminum-zinc oxide (InAlZnO)-based material, or a tin-aluminum-zinc oxide (SnAlZnO)-based material, which is a ternary metal oxide, an indium-zinc oxide (InZnO)-based material, a tin-zinc oxide (SnZnO)-based material, an aluminum-zinc oxide (AlZnO)-based material, a zinc-magnesium oxide (ZnMgO)-based material, a tin-magnesium oxide (SnMgO)-based material, an indium-magnesium oxide (InMgO)-based material, or an indium-gallium oxide (InGaO)-based material, which is a binary metal oxide, an indium oxide (InO)-based material, a tin oxide (SnO)-based material, a zinc oxide (ZnO)-based material, or the like, without being limited to a composition ratio of elements thereof.

The semiconductor layer 124 may include a source region, a drain region, and a channel region between the source region and the drain region, all of which include a p-type or n-type impurity. The semiconductor layer 124 may further include a low-concentration doping region between the source region and the drain region adjacent to the channel region.

The source region and the drain region are regions in which an impurity is doped in a high concentration. The source electrode 122 and the drain electrode 123 of the thin film transistor 120 may be connected to the source region and the drain region, respectively.

As impurity ions, a p-type impurity or an n-type impurity may be used. The p-type impurity may be one of boron (B), aluminum (Al), gallium (Ga), and indium (In). The n-type impurity may be one of phosphorous (P), arsenic (As), antimony (Sb), or the like.

The semiconductor layer 124 may be doped with an n-type impurity or a p-type impurity in the channel region thereof in accordance with an NMOS or PMOS thin film transistor structure. For thin film transistors included in the flexible display device 100 according to the aspect of the present disclosure, NMOS or PMOS thin film transistors are applicable.

The gate insulating layer 114 is an insulating layer constituted by a single layer of silicon oxide (SiOₓ) or silicon nitride (SiNₓ) or multiple layers thereof. The gate insulating layer 114 may be disposed to prevent a current flowing through the semiconductor layer 124 from flowing into the gate electrode 121. Although silicon oxide has lower softness than that of metal, silicon oxide has excellent softness, as compared to silicon nitride, and, as such, may be formed in the form of a single layer or a plurality of layers in accordance with characteristics thereof.

The gate electrode 121 functions to perform a switching operation for turning on or off the thin film transistor 120 based on an electrical signal transmitted thereto from outside through a gate line. The gate electrode 121 may be constituted by a single layer of a conductive metal such as copper (Cu), aluminum (Al), molybdenum (Mo), chromium (Cr), gold (Au), titanium (Ti), nickel (Ni), neodymium (Nd), or an alloy thereof, or multiple layers thereof, without being limited thereto.

The source electrode 122 and the drain electrode 123 are connected to a data line and may function to enable an electrical signal transmitted thereto from outside to be transmitted to a light emitting element 160. The source electrode 122 and the drain electrode 123 may be constituted by a single layer of a conductive metal such as copper (Cu), aluminum (Al), molybdenum (Mo), chromium (Cr), gold (Au), titanium (Ti), nickel (Ni), neodymium (Nd), or an alloy thereof, or multiple layers thereof, without being limited thereto.

An interlayer insulating layer 115, which is constituted by a single layer of silicon oxide (SiOₓ) or silicon nitride (SiNₓ) or multiple layers thereof, may be disposed among the gate electrode 121, the source electrode 122, and the drain electrode 123 to insulate the gate electrode 121, the source electrode 122, and the drain electrode 123 from one another.

A passivation layer constituted by an inorganic insulating layer of silicon oxide (SiOₓ) or silicon nitride (SiNₓ) may be further disposed over the thin film transistor 120.

The passivation layer may function to prevent unnecessary electrical connection among constituent elements disposed over and under the passivation layer and to prevent contamination, damage, etc. of the constituent elements from outside. The passivation layer may be omitted in accordance with configurations and characteristics of the thin film transistor 120 and the light emitting element 160.

The thin film transistor 120 may be classified into an inverted staggered structure or a coplanar structure in accordance with positions of constituent elements constituting the thin film transistor 120. For example, in the case of a thin film transistor having an inverted staggered structure, a gate electrode thereof may be disposed at a side opposite to source and drain electrodes thereof. In the case of the thin film transistor 120, which has a coplanar structure, the gate electrode 121 may be disposed at the same side as the source electrode 122 and the drain electrode 123 with reference to the semiconductor layer 124, as shown in FIG. 4.

Although the thin film transistor 120 having the coplanar structure is shown in FIG. 4, the flexible display device 100 according to the aspect of the present disclosure may include a thin film transistor having an inverted staggered structure.

Although, among various thin film transistors, which may be included in the flexible display device 100, only a driving thin film transistor is shown for convenience of description. A switching thin film transistor, a capacitor, etc. may be included in the flexible display device 100.

In addition, the switching thin film transistor transmits a signal from the data line to the gate electrode of the driving thin film transistor upon receiving a signal from the gate line. The driving thin film transistor may transmit, to an anode 131, a current transmitted through a power line in accordance with the signal received from the switching thin film transistor, and may control light emission by the current transmitted to the anode 131.

A planarization layer 116 may be disposed over the thin film transistor 120 to protect the thin film transistor 120, to reduce a step formed due to the thin film transistor 120, and to reduce a parasitic capacitance generated among the thin film transistor 120, the gate line, the data line, and the light emitting element 160.

The planarization layer 116 may be formed of at least one of an acrylic resin, an epoxy resin, a phenolic resin, a polyamide resin, a polyimide resin, an unsaturated polyester resin, a polyphenylene resin, a polyphenylene sulfide resin, and benzocyclobutene, without being limited thereto.

The flexible display device 100 according to the aspect of the present disclosure may include a first planarization layer and a second planarization layer which are sequentially stacked.

The light emitting element 160 disposed over the planarization layer 116 may include the anode 131, an emission portion 132, and a cathode 133.

The anode 131 may be disposed over the planarization layer 116.

The anode 131, which is an electrode functioning to supply holes to the emission portion 132, may be electrically connected to the drain electrode 123 of the thin film transistor 120 through a contact hole disposed at the planarization layer 116.

The anode 131 may be constituted by indium tin oxide (ITO), indium zinc oxide (IZO), or the like, which is a transparent conductive material, without being limited thereto.

When the flexible display device 100 has a top emission structure in which light is emitted toward an upper side where the cathode 133 is disposed, the flexible display device 100 may further include a reflective layer to enable the emitted light to be more efficiently discharged toward the upper side where the cathode 133 is disposed.

The anode 131 may have a double-layer structure in which a transparent conductive layer constituted by a transparent conductive material and a reflective layer are sequentially stacked or a triple-layer structure in which a transparent conductive layer, a transparent layer, and a transparent conductive layer are sequentially stacked. The reflective layer may be constituted by silver (Ag) or an alloy including silver.

A bank 117 may be disposed over the anode 131 and the planarization layer 116. The bank 117 may partition a region in which light is actually emitted, thereby defining a sub-pixel.

The emission portion 132 may be disposed between the anode 131 and the cathode 133.

The emission portion 132, which functions to emit light, may include at least one of a hole injection layer (HIL), a hole transport layer (HTL), an emission layer, an electron transport layer (ETL), and an electron injection layer (EIL), and a part of the constituent elements as described above may be omitted in accordance with a structure or characteristics of the flexible display device 100. Here, as the emission layer, an electroluminescent layer and an inorganic emission layer are also applicable.

The hole injection layer may be disposed over the anode 131 to function to achieve efficient hole injection.

The hole transport layer may be disposed over the hole injection layer to function to achieve efficient hole transport.

The emission layer may be disposed over the hole transport layer and may include a material capable of emitting light of a particular color and, as such, may emit light of the particular color. In addition, as the emission material, a phosphorescent material or a fluorescent material may be used.

The electron injection layer may be further disposed over the electron transport layer. The electron injection layer is an organic layer functioning to achieve efficient injection of electrons from the cathode 133. The electron injection layer may be omitted in accordance with a structure and characteristics of the flexible display device 100.

Meanwhile, an electron blocking layer or a hole blocking layer, which functions to block a flow of electrons or holes, may be further disposed at a position adjacent to the emission layer. The electron blocking layer or the hole blocking layer prevents a phenomenon in which electrons move from the emission layer to pass through the hole transport layer adjacent to the emission layer after being injected into the emission layer or holes move from the emission layer to pass through the electron transport layer adjacent to the emission layer after being injected into the emission layer, thereby achieving an enhancement in luminous efficacy.

The cathode 133 is disposed over the emission portion 132 to supply electrons to the emission portion 132. Since the cathode 133 should supply electrons, the cathode 133 may be constituted by a metal material such as magnesium (Mg), silver-magnesium (Ag:Mg), or the like, which is a conductive material having low work function, without being limited thereto.

When the flexible display device 100 is of a top emission type, the cathode 133 may be constituted by a transparent conductive oxide of indium tin oxide (ITO), indium zinc oxide (IZO), indium tin zinc oxide (ITZO), zinc oxide (ZnO), or tin oxide (TO).

An encapsulator 118 may be disposed over the light emitting element 160 to prevent the thin film transistor 120 and the light emitting element 160, which are constituent elements of the flexible display device 100, from being oxidized or damaged by moisture, oxygen or impurities introduced from outside. The encapsulator 118 may be formed through stacking of a plurality of encapsulation layers, a foreign matter compensation layer, and a plurality of barrier films.

An encapsulation layer may be disposed over the entire upper surface of the thin film transistor 120 and the entire upper surface of the light emitting element 160. The encapsulation layers may be constituted by one of silicon nitride (SiNₓ) or aluminum oxide (AlyO_{z}) which is an inorganic material, without being limited thereto. A foreign matter compensation layer is disposed on the encapsulation layer, and another encapsulation layer may be further disposed on the foreign matter compensation layer.

The foreign matter compensation layer, which is disposed on the encapsulation layer, may be constituted by silicon oxycarbon (SiOC_{z}), which is an organic material, or a resin of acryl or epoxy series, without being limited thereto. When a defect is generated due to a crack formed by foreign matter or particles possibly generated during a process, the foreign matter compensation layer covers the foreign matter and a curvature formed by the foreign matter, thereby compensating for the defect.

A barrier film may be disposed over the encapsulation layer and the foreign matter compensation layer to delay penetration of oxygen and moisture from outside into the flexible display device 100. The barrier film may be configured to take the form of a film exhibiting transparency and double-sided adhesiveness, and may be constituted by an insulating material of olefin, acryl, or silicon series. In addition, a barrier film constituted by one of cycloolefin polymer (COP), cycloolefin copolymer (COC), and polycarbonate (PC) may be further stacked, without being limited thereto.

Although not shown, touch electrodes may be disposed over the encapsulator 118.

A light shielding layer 141 may be formed between the buffer layer 112 and the substrate 111 to cover the semiconductor layer 124 of the thin film transistor 120. The light shielding layer 141 may function to prevent the semiconductor layer 124 of the thin film transistor 120 from being irradiated with light.

The light shielding layer 141 may be formed of metal.

Meanwhile, a meltable metal pattern 142 is formed in a trimming region between at least two OLED display panel regions. As a material of the meltable metal pattern 142, a metal material having a low melting point, such as lead (Pb), copper (Cu), aluminum (Al), silver (Ag), or the like, may be used.

The light shielding layer 141 and the meltable metal pattern 142 may be formed on the same layer using the same metal material.

The meltable metal pattern 142 may be separately formed, differently from a material layer in each OLED display panel region.

Hereinafter, a method of manufacturing a display device using the mother substrate of the OLED display panel 100, in which at least two OLED display panel regions and a trimming region between the at least two OLED display panel regions are provided at the mother substrate, and the meltable metal pattern 142 is formed in the trimming region, as described with reference to FIG. 4, will be described.

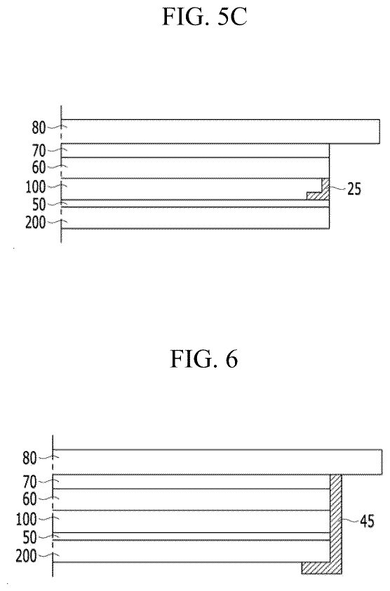

FIGS. 5A to 5C are process sectional views explaining a method of manufacturing the flexible OLED display device according to the first aspect of the present disclosure.

As shown in FIG. 5A, an OLED display panel 100 and a polarization plate 60, which are configured as described with reference to FIG. 4, are disposed on a back plate 200.

Thereafter, the back plate 200 and the OLED display panel 100 are bonded to each other by an adhesive (PSA) 50.

In addition, a transparent adhesive (OCA) 70 is bonded to an upper surface of the polarization plate 60. Although not shown, both surfaces of the transparent adhesive (OCA) 70 are protected by protection films, respectively. Accordingly, the transparent adhesive (OCA) 70 is bonded to the upper surface of the polarization plate 60 under the condition that the protection film on one surface of the transparent adhesive (OCA) 70 has been removed.

A laser is irradiated onto a central portion of a meltable metal pattern 142 formed in a trimming region between at least two OLED display panel regions, as described with reference to FIG. 4, thereby dividing (cutting) the resultant structure of FIG. 5A into unit OLED display panel regions. The laser is irradiated at the side of a back surface of the back plate 200.

As shown in FIG. 5B, the back plate 200, the adhesive (PSA) 50, the OLED display panel 100, the polarization plate 60, and the transparent adhesive (OCA) 70 are cut into unit OLED display panel regions by the laser.

At the same time, the meltable metal pattern 142 is melted by heat of the laser, thereby sealing a side surface of the OLED display panel 100.

That is, as the meltable metal pattern 142 is melted by heat of the laser, the meltable metal pattern 142 may become a sealing member 25 to seal the side surface of the OLED display panel 100, as described with reference to FIG. 3.

Thereafter, the protection film remaining on the surface of the transparent adhesive (OCA) 70 in a state in which the structure has been cut into the unit OLED display panel regions is removed, and a cover glass 80 is then bonded to the surface of the transparent adhesive (OCA) 70, as shown in FIG. 5C.

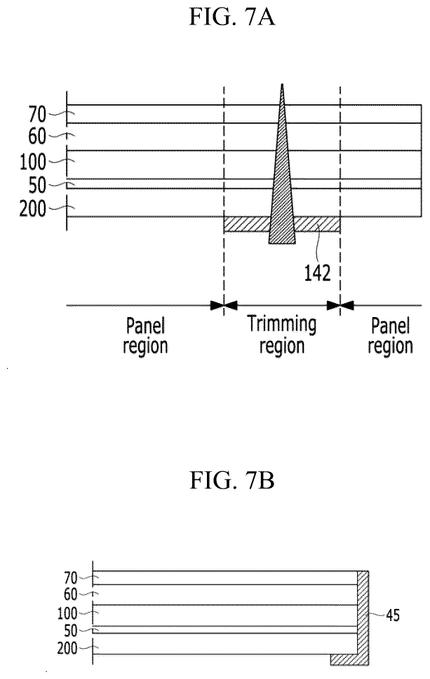

FIG. 6 is a sectional view schematically showing a configuration of one end of the flexible OLED display device a flexible OLED display device according to a second aspect of the present disclosure.

As shown in FIG. 6, the flexible OLED display device according to the second aspect of the present disclosure may be configured through inclusion of a back plate 200, an OLED display panel 100, a polarization plate 60, and a cover glass 80.

The back plate 200 and the OLED display panel 100 are bonded to each other by an adhesive (PSA) 50. The polarization plate 60 is disposed on the OLED display panel 100, and the polarization 60 and the cover glass 80 are bonded to each other by a transparent adhesive (OCA) 70.

In addition, side surfaces of the back plate 200, the adhesive (PSA) 50, the OLED display panel 100, the polarization plate 60, and the transparent adhesive (OCA) 70 may be sealed by a sealing member 45 formed by a meltable metal.

In this case, as the meltable metal of the sealing member 45, a metal material having a low melting point, such as lead (Pb), copper (Cu), aluminum (Al), silver (Ag), or the like, may be used.

Hereinafter, a method of manufacturing the flexible OLED display device according to the second aspect of the present disclosure having the above-described structure will be described.

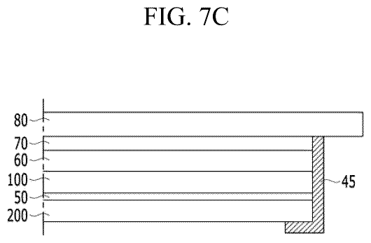

FIGS. 7A to 7C are process sectional views explaining the method of manufacturing the flexible OLED display device according to the second aspect of the present disclosure.

Hereinafter, a method of manufacturing a display device using a mother substrate of an OLED display panel 100, in which at least two OLED display panel regions and a trimming region between the at least two OLED display panel regions are provided at the mother substrate, will be described.

As shown in FIG. 7A, the OLED display panel 100 and a polarization plate 60 are disposed on a back plate 200.

Thereafter, the back plate 200 and the OLED display panel 100 are bonded to each other by an adhesive (PSA) 50.

A transparent adhesive (OCA) 70 is bonded to an upper surface of the polarization plate 60. Although not shown, both surfaces of the transparent adhesive (OCA) 70 are protected by protection films, respectively. Accordingly, the transparent adhesive (OCA) 70 is bonded to the upper surface of the polarization plate 60 under the condition that the protection film on one surface of the transparent adhesive (OCA) 70 has been removed.

In addition, a meltable metal pattern 142 is formed at a back surface of the back plate 200 in a trimming region.

A laser is irradiated onto a central portion of the meltable metal pattern 142 formed in the trimming region between at least two OLED display panel regions, thereby dividing (cutting) the resultant structure of FIG. 7A into unit OLED display panel regions. The laser is irradiated at the side of the back surface of the back plate 200.

As a result, as shown in FIG. 7B, the back plate 200, the adhesive (PSA) 50, the OLED display panel 100, the polarization plate 60, and the transparent adhesive (OCA) 70 are cut into unit OLED display panel regions by the laser.

At the same time, the meltable metal pattern 142 is melted by heat of the laser, thereby sealing side surfaces of the back plate 200, the adhesive (PSA) 50, the OLED display panel 100, the polarization plate 60, and the transparent adhesive (OCA) 70.

That is, as the meltable metal pattern 142 is melted by heat of the laser, the side surfaces of the back plate 200, the adhesive (PSA) 50, the OLED display panel 100, the polarization plate 60, and the transparent adhesive (OCA) 70 may be sealed by a sealing member 25 formed by the melted metal of the meltable metal pattern 142.

Thereafter, the protection film remaining on the surface of the transparent adhesive (OCA) 70 in a state in which the structure has been cut into the unit OLED display panel regions is removed, and a cover glass 80 is then bonded to the surface of the transparent adhesive (OCA) 70, as shown in FIG. 7C.

As apparent from the above description, in the flexible OLED display device according to the first aspect of the present disclosure, it may be possible to prevent moisture from being introduced into the OLED display panel 100 because the meltable metal pattern 142 is melted when cutting is carried out on the basis of a unit OLED display device and, as such, the side surface of the OLED display panel 100 is sealed by a melted metal of the meltable metal pattern 142.

In addition, in the flexible OLED display device according to the second aspect of the present disclosure, it may be possible to prevent moisture from being introduced into the OLED display device because the meltable metal pattern 142 is melted when cutting is carried out on the basis of a unit OLED display device and, as such, the side surfaces of the back plate 200, the adhesive (PSA) 50, the OLED display panel 100, the polarization plate 60, and the transparent adhesive (OCA) 70 are sealed by a melted metal of the meltable metal pattern 142.

In addition, in the flexible OLED display device according to the first or second aspect of the present disclosure, process simplification may be achieved because the side surface of the OLED display panel 100 or the side surface of the display device is sealed by a melted metal when cutting is carried out on the basis of a unit OLED display device.

It will be apparent to those skilled in the art that various modifications and variations can be made in the display device and a method of manufacturing the same of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A display device comprising:
a back plate;
a display panel bonded onto the back plate;
a cover glass bonded onto the display panel; and
a sealing member configured to seal a side surface of the display panel and formed of a meltable metal.

2. The display device according to claim 1, wherein the meltable metal of the sealing member comprises one of lead, copper, aluminum, and silver.

3. The display device according to claim 1, further comprising:
a polarization plate disposed between the display panel and the cover glass,
wherein the back plate and the display panel are bonded to each other by an adhesive, and
wherein the cover glass and the polarization plate are bonded to each other by a transparent adhesive.

4. A display device comprising:
a back plate;
a display panel bonded onto the back plate;
a cover glass bonded onto the display panel; and
a sealing member configured to seal side surfaces of the back plate and the display panel and formed of a meltable metal.

5. The display device according to claim 4, wherein the meltable metal of the sealing member includes one of lead, copper, aluminum, and silver.

6. The display device according to claim 4, further comprising a polarization plate disposed between the display panel and the cover glass,
wherein the back plate and the display panel are bonded to each other by an adhesive, and
wherein the cover glass and the polarization plate are bonded to each other by a transparent adhesive.

7. The display device according to claim 6, wherein the sealing member further seals side surfaces of the polarization plate, the adhesive and the transparent adhesive.

8. A method of manufacturing a display device, comprising:
preparing a display panel comprising at least two organic light emitting display, OLED, display panel regions, and a trimming region disposed between the at least two OLED display panel regions and formed with a meltable metal pattern;
bonding the display panel onto a back plate;
bonding a transparent adhesive to an upper surface of the display panel; and
irradiating a central portion of the meltable metal pattern formed in the trimming region with a laser, thereby cutting a resultant structure comprising the display panel, back plate and the transparent adhesive into unit OLED display panel regions and, simultaneously, melting the meltable metal pattern by heat of the laser, to form a sealing member configured to seal a side surface of the display panel.

9. The method according to claim 8, wherein the meltable metal pattern includes one of lead, copper, aluminum, and silver.

10. The method according to claim 8, further comprising disposing a polarization plate between the upper surface of the display panel and the transparent adhesive.

11. The method according to claim 8, wherein the laser is irradiated at the side of the back surface of the back plate.

12. The method according to claim 11, further comprising bonding a cover glass onto the transparent adhesive cut into the unit OLED display panel regions.

13. The method according to claim 8, wherein each of the at least two OLED display panel regions comprises a thin film transistor, and a light shielding layer disposed under the thin film transistor, and
wherein the light shielding layer and the meltable metal pattern are formed on a same layer using a same material.

14. A method of manufacturing a display device, comprising:
preparing a display panel comprising at least two organic light emitting display, OLED, display panel regions, and a trimming region disposed between the at least two OLED display panel regions;
bonding the display panel onto a back plate;
bonding a transparent adhesive to an upper surface of the display panel;
forming a meltable metal pattern at a back surface of the back plate in the trimming region; and
irradiating a central portion of the meltable metal pattern with a laser, thereby cutting a resultant structure comprising the display panel, back plate and the transparent adhesive into unit OLED display panel regions and, simultaneously, melting the meltable metal pattern by heat of the laser, to form a sealing member configured to seal side surfaces of the back plate, the display panel, and the transparent adhesive.

15. The method according to claim 14, wherein the meltable metal pattern comprises one of lead, copper, aluminum, and silver.

16. The method according to claim 14, further comprising bonding a cover glass onto the transparent adhesive cut into the unit OLED display panel regions.
